(19) United States
(12) Patent Application Publication
(10) Pub. No.: US 2004/0158667 A1
(43) Pub. Date: Aug. 12, 2004

(54) Packet switched backplane

(76) Inventor: Brian Andrew Carr, Loughborough (GB)

Correspondence Address: MOTOROLA, INC., CORPORATE LAW DEPARTMENT - #56-238, 3102 NORTH 56TH STREET, PHOENIX, AZ, 85018, US

(21) Appl. No.: 10/737,362

(22) Filed: Dec. 16, 2003

(30) Foreign Application Priority Data
Aug. 1, 2002 (GB) 0318044.5

(51) Int. Cl. H05K 7/10; H04J 3/16

(52) U.S. Cl. 710/301; 370/465

(57) ABSTRACT

A packet switched backplane (100) having a plurality of node slots (102 through 106) wherein at least portion of said node slots comply with the PICMG 2.16 standard. At least one of said node slots (104, 106) complying with said PICMG 2.16 node standard is connected by means of dedicated links (124) to at least one another node slot (102) complying with said PICMG 2.16 node standard (aggregation slot).

### FIELD OF THE INVENTION

The present invention relates to data processing systems, in general, and to packet switched backplane for communication and data transfer, in particular.

### BACKGROUND OF THE INVENTION

Computer systems consist of many different components that perform various functions. For interconnection these components use a backplane which provides high rates of data transfers between components. In Compact PCI standard, Ethernet or IP communication between these components are provided by means of cables connecting said components with an external Ethernet switch. Said external switch is responsible for communication between components (cards) as wells as for communication with external world. Using cable for establishing connection between cards is not perfect solution as it introduces additional risk and takes space for the cables and the external Ethernet switch.

Introduction of the PICMG 2.16 standard solved the problem of cabling and the external Ethernet switch. According to this standard an Ethernet switch is a part of a special dedicated card (called fabric card) and the cabling was brought inside the backplane. In PICMG 2.16 there are two types of cards defined:

1) A fabric card which is a dedicated central interface card responsible for switching of Ethernet signals to and from other cards (also called node cards) on the backplane as well as for switching incoming and outgoing traffic.

2) A node card which is a processing card designed to perform particular functions according to technical requirements.

According to the PICMG 2.16 standard, one or two fabric cards may be connected to one backplane. As the mentioned standard is designed for packet traffic, routing from one node card to another node card is done via said fabric card. Each node card is linked directly to fabric card using traces that can support 10/100/1000 BaseT Ethernet. If there are two fabric cards in one system (on one backplane), node cards are linked directly to each fabric card. In turn, each of these fabric cards can perform switching/routing for the entire chassis and features gigabit Ethernet connections to a LAN/WAN, so providing reliability in case of link or fabric card failure.

Solutions based on PICMG 2.16 standard architecture are widely accepted and used in intensive IP applications. Large systems can support more than 16 node slots. However, for small systems comprising fewer than 6 slots, the overhead of the fabric card with said Ethernet switch is often too high to compete with proprietary developments that do not use open standards based card architectures.

### SUMMARY OF THE INVENTION

There is a need for a packet switched backplane, which alleviate or overcome the disadvantages of the prior art.

According to a first aspect of the present invention there is thus provided a packet switched backplane having a plurality of node slots wherein at least two of said node slots comply with the PICMG 2.16 node standard. At least one of said node slots complying with said PICMG 2.16 node standard is connected by means of dedicated links to at least one aggregation slot, said aggregation slot comprising at least one other node slot complying with said PICMG 2.16 node standard.

According to a second aspect of the present invention there is thus provided a data processing system comprising a packet switched backplane having a plurality of node slots wherein at least two of said node slots comply with the PICMG 2.16 standard. A plurality of node cards are connected to said node slots and dedicated links connect Ethernet transmit pins of at least one of said node slots to Ethernet receive pins of at least one aggregation slot, said aggregation slot comprising at least one other node slot as well as connect Ethernet receive pins of at least one of said node slots to Ethernet transmit pins of said aggregation slot to make a direct point-to-point Ethernet connection. An aggregation card comprising a node card equipped with an Ethernet bridging unit, and an external Ethernet connector is connected to said aggregation slot and said Ethernet bridging unit bridges between said node cards and external addresses by means of said external Ethernet connector.

The present invention beneficially allows reducing the overall cost of the system and better utilization of its main components. For systems that must use node cards which are equipped with an Ethernet switch as a standard it is possible to use this type of cards not only for the originally designed functions but also to be a core of the internal network (connection with other node cards). Such card can be responsible also for providing an IP connection to external addresses by means of said external Ethernet connector. For such systems a fabric card is not required.

Advantages of the present invention include:

1) Significantly reduced cost of the system;

2) Only standard equipment is used for development and deployment of the system allowing the reuse of totally standard PICMG 2.16 node cards;

3) Equipment and space saving: no need for a specific fabric card which takes up a slot and space in a chassis;

4) Potentially automatic forwarding resulting in no impact on software used to control the system.

### BRIEF DESCRIPTION OF THE DRAWINGS

The present invention will be understood and appreciated more fully from the following detailed description taken in conjunction with the drawings in which:

FIG. 1 is a schematic illustration of a portion of connections in the backplane in one embodiment of the present invention,

FIG. 2 is a block diagram illustrating a data processing system in one embodiment of the present invention,

FIG. 3 is a block diagram illustrating a data processing system in a High Availability approach, in one embodiment of the present invention,

FIG. 4 is a schematic illustration of a portion of connections in the backplane in a High Availability approach, in one embodiment of the present invention.

### DETAILED DESCRIPTION OF AN EMBODIMENT OF THE INVENTION

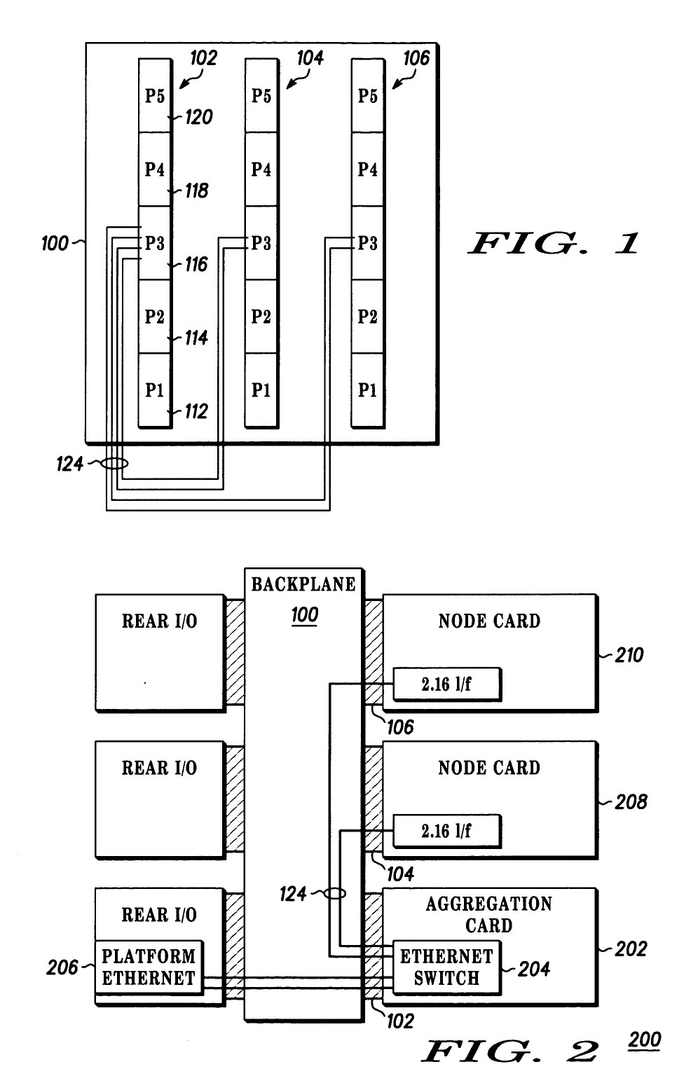

Referring to FIG. 1 one embodiment of a packet switched backplane according to the present invention is shown. A backplane 100 is comprised of node slots 102 through 106 for connection of Compact PCI cards. Each of said node slots 102 through 106 is comprised of 5 rows of connectors 112 through 120 arranged according to PICMG 2.0 (Compact PCI base specification) and again defined in PICMG 2.16 standard for node cards. Said rows of connection pins 112, 114, 116, 118, 120 are referred to as P1, P2, P3, P4 and P5 respectively. Said P1 pins are the ones on the bottom of said node slots and said P5 pins are the ones on the top of said slots. PICMG 2.16 standard for node card defines Ethernet transmit and receive pins in the P3 connector. In one embodiment of the present invention dedicated links 124 between a first node slot 102 and remaining node slots 104, 106 exist. Receiving (RX) pins of said P3 rows of said node slots 104, 106 are connected to transmitting (TX) pins of said P3 row 116 of said first node slot. Said first node slot 102 is referred to as an aggregation slot because its function is to aggregate and distribute Ethernet traffic throughout the small system. Additionally TX pins of said P3 rows of said node slots 104, 106 are connected to RX pins of said P3 row 116 of said aggregation slot 102.

Referring to FIG. 4 one embodiment of a packet switched backplane in a High Availability approach according to the present invention is shown. A backplane 320 is comprised of node slots 322, 324, 328, 330 for connection of Compact PCI cards. Each of said node slots 322, 324, 328, 330 having connectors 112 through 120 arranged according to PICMG 2.0 (Compact PCI base specification) and again defined in PICMG 2.16 standard for node cards as it was explained above in relation to FIG. 1. In one embodiment of the present invention dedicated links 326 between a first node slot 322 and two other node slots 328 and 330 exist. RX pins of said P3 rows of said node slots 328 and 330 are connected to TX pins of said P3 row 116 of said first node slot 322. Said first node slot 322 is referred to as an aggregation slot. Additionally TX pins of said P3 rows of said node slots 328 and 330 are connected to RX pins of said P3 row 116 of said aggregation slot 322. In addition said node slots 328 and 330 are connected by means of links 326 in exactly the same way to a second aggregation slot 324.

With reference to FIG. 2 a data processing system 200 in accordance with one embodiment of the present invention is shown. If a first card 202 connected to said aggregation slot 102 is equipped with an Ethernet switch 204 said first card 202 will provide internal communication between cards 208, 210 (also known as node cards) connected to said backplane 100. Said internal communication is carried out via said dedicated links 124. Said card 202 connected to said aggregation slot 102 is further referred to as an aggregation card. Additionally by means of an external Ethernet connection 206 said aggregation card 202 bridges between said node cards 208, 210 and external addresses.

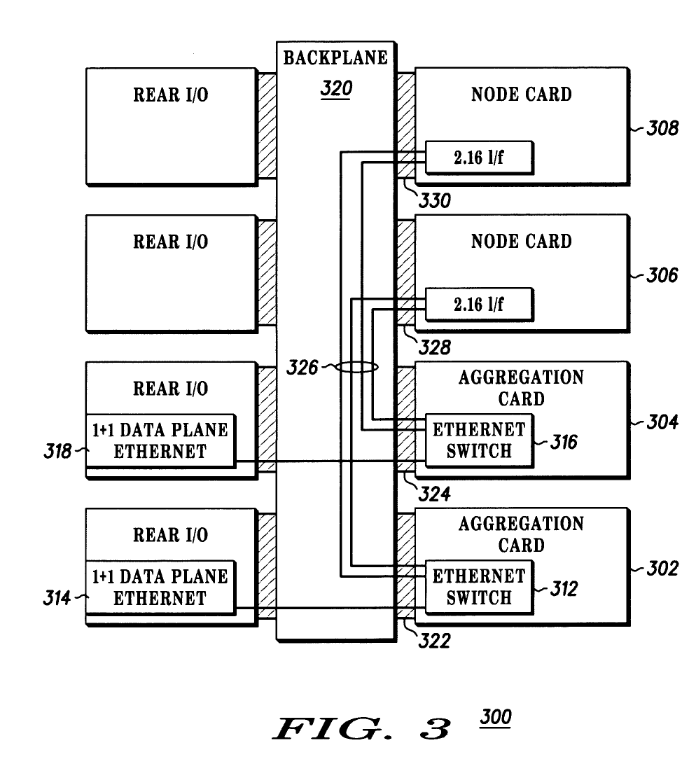

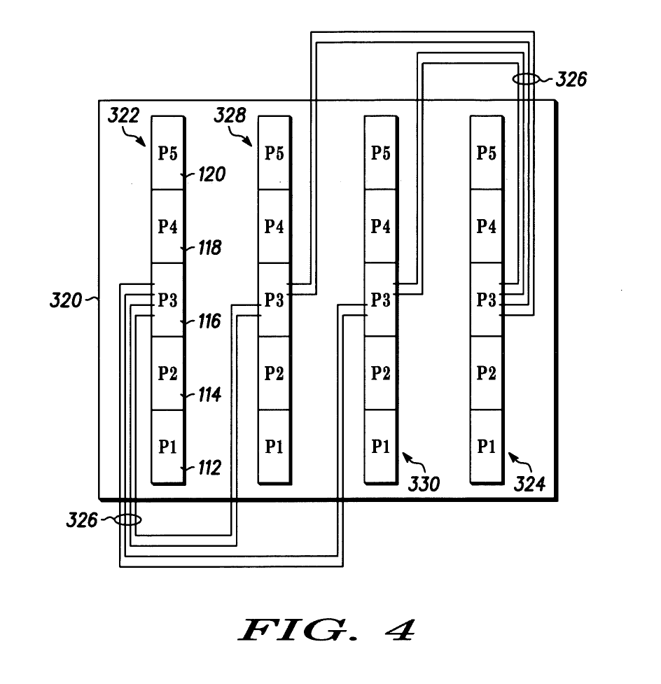

With reference to FIG. 3 a data processing system 300 in accordance with another embodiment of the present invention is shown. In this embodiment a High Availability approach is applied. Two aggregation cards 302 and 304 are connected to a backplane 320 via two aggregation slots 322 and 324. Two node cards 306, 308 are connected to a backplane 320 via two node slots 328, 330. In said backplane 320 dedicated links 326 connect each of said node slots 328, 330 to both aggregation slots 322 and 324. Connections between any one of said node slots 328, 330 and any one of said aggregation slots 322 and 324 are provided in exactly the same way as those explained in relation to FIG. 1. By means of Ethernet switches 312 and 316 said aggregation cards 302 and 304 provide internal communication between all node cards 306, 308 connected to said backplane 320. By means of said Ethernet switches 312 and 316 as well as external Ethernet connections 314 and 318 said aggregation cards 302 and 304 bridge between said node cards 306, 308 and external addresses.

It is worth to emphasise that said aggregation card is in fact a node card (in terms of PICMG 2.16 standard) capable of performing technical function in addition to Ethernet packet routing, and its specific (aggregation) function is caused by the fact that it is possible to use the installed Ethernet switch or other Ethernet bridging unit for establishing an internal and external communication.

For specific embodiments dedicated cards, like Motorola PVRB series or PCRB series cards may be used.

System with said PVRB series card as an aggregation card can perform many voice/media over IP functions like voice media gateways (for both wireline and wireless functions), media server and media streaming applications.

In yet another embodiment system with said PCRB series card can perform many IP packet inspection, processing, and routing functions that could be used for example in deep packet classification security gateways, network address translation, load balancing, and other packet streaming applications.

1. A packet switched backplane having a plurality of node slots wherein at least two of said node slots comply with the PICMG 2.16 node standard characterized in that at least one of said node slots complying with said PICMG 2.16 node standard is connected by means of dedicated links to at least one aggregation slot, said aggregation slot comprising at least one other node slot complying with said PICMG 2.16 node standard.

2. The backplane according to claim 1 wherein Ethernet transmit pins of said node slots are connected to Ethernet receive pins of said aggregation slot and Ethernet receive pins of said node slots are connected to Ethernet transmit pins of said aggregation slot.

3. The backplane according to claim 1 wherein at least one of said node slots is connected to two of said aggregation slots.

4. The backplane according to claim 1 having at least one fabric slot that comply with PICMG 2.16 standard.

5. A data processing system comprising a packet switched backplane having a plurality of node slots wherein at least two of said node slots comply with the PICMG 2.16 standard and a plurality of node cards connected to said node slots characterized in that dedicated links connect Ethernet transmit pins of at least one of said node slots to Ethernet receive pins of at least one aggregation slot, said aggregation slot comprising at least one other node slot as well as connect Ethernet receive pins of at least one of said node slots to Ethernet transmit pins of said aggregation slot to make a direct point-to-point Ethernet connection wherein an aggregation card comprising a node card equipped with an Ethernet bridging unit and an external Ethernet connector is connected to said aggregation slot and said Ethernet bridging unit bridges between said node cards and external addresses by means of said external Ethernet connector.

6. The data processing system according to claim 5 wherein said Ethernet bridging unit is an Ethernet switch.

7. The data processing system according to claim 5 wherein each of said node cards is connected to two aggregation cards.

8. The data processing system according to claim 5 wherein said aggregation card is a Motorola PVRB series card.

9. The data processing system according to claim 5 wherein said aggregation card is a Motorola PCRB series card.
